(19) United States
(12) Patent Application Publication
(10) Pub. No.: US 2014/0306318 A1
(43) Pub. Date: Oct. 16, 2014

(54) TRENCH FORMATION METHOD AND A SEMICONDUCTOR STRUCTURE THEREOF

(71) Applicant: Silergy Semiconductor Technology (Hangzhou) LTD, Hangzhou (CN)

(72) Inventor: Liang Tong, Hangzhou (CN)

(73) Assignee: Silergy Semiconductor Technology (Hangzhou) LTD, Hangzhou (CN)

(21) Appl. No.: 14/227,894

(22) Filed: Mar. 27, 2014

(30) Foreign Application Priority Data
Apr. 12, 2013 (CN) 201310130921.5

(51) Int. Cl. H01L 21/308; H01L 29/06

(52) U.S. Cl. CPC H01L 21/3083; H01L 29/0649
USPC 257/506; 438/702

(57) ABSTRACT

In one embodiment, a method of making a trench for a semiconductor device can include: (i) providing a semiconductor substrate; (ii) forming a patterned hard mask layer with an opening on the semiconductor substrate, where a thickness of the patterned hard mask layer is from about 100 nm to about 400 nm; and (iii) using the patterned hard mask layer as a mask, and etching the semiconductor substrate to form the trench in the semiconductor substrate.

### RELATED APPLICATIONS

This application claims the benefit of Chinese Patent Application No. 201310130921.5, filed on Apr. 12, 2013, which is incorporated herein by reference in its entirety.

### FIELD OF THE INVENTION

The present invention relates to integrated circuit manufacture processes, and more particularly to a trench formation method and associated semiconductor structure.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. In this way, the output voltage and/or the output current of the switching power supply can be maintained as substantially constant. Therefore, the selection and design of the particular control circuitry and approach is very important to the overall performance of the switching power supply. Thus, using different detection signals and/or control circuits can result in different control effects on power supply performance.

### SUMMARY

In one embodiment, a method of making a trench for a semiconductor device can include: (i) providing a semiconductor substrate; (ii) forming a patterned hard mask layer with an opening on the semiconductor substrate, where a thickness of the patterned hard mask layer is from about 100 nm to about 400 nm; and (iii) using the patterned hard mask layer as a mask, and etching the semiconductor substrate to form the trench in the semiconductor substrate.

In one embodiment, a semiconductor structure can include: (i) a semiconductor substrate; (ii) a trench in the semiconductor substrate, where the trench comprises a first sidewall adjacent to a surface of the semiconductor substrate, and second sidewall connected to the first sidewall, where an angle between the first sidewall and the surface is acute; and (iii) a fill layer in the trench, where the fill layer is selected from a polysilicon layer and an isolation layer.

Embodiments of the present invention can provide several advantages over conventional approaches, as may become readily apparent from the detailed description of preferred embodiments below.

### BRIEF DESCRIPTION OF THE DRAWINGS

FIG. 1 is a cross-sectional diagram of an example trench formation.

FIG. 2 is a cross-sectional diagram of an example trench with spacer formation.

FIG. 3 is a flow diagram of an example method of making a trench in accordance with embodiments of the present invention.

FIGS. 4A-4G are cross-sectional diagrams of example trench formation processing, in accordance with embodiments of the present invention.

FIG. 5 is a schematic diagram of an example synchronous switching voltage regulator, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

A power device (e.g., a metal oxide semiconductor field-effect transistor [MOSFET]) can be utilized in a power supply or regulator (e.g., a switching voltage regulator). Power losses through the power device or transistor can be reduced by reducing the conductive resistance of the MOSFET device. One type of transistor that is suitable for power device application is a vertical diffused MOS (VDMOS), which is also sometimes referred to as a double-diffused MOS (DMOS), or a vertical double-diffusion MOS (VDMOS). In a VDMOS, the source electrode is placed over the drain, resulting in a current that is mainly vertical when the transistor is in the on-state.

A power device with a trench structure can be utilized as a power transistor in a switching power supply. In this case, the gate of the power transistor can be formed by growth of a gate oxide and fill-in of polysilicon over sidewalls of the trench, such as to substantially fill the trench. In this way, the planar surface area of the power transistor can be utilized more efficiently to obtain a larger effective channel width and current density of unit device per unit area to achieve increased current carrying capacity for the power device.

However, because the sidewalls are generally substantially vertical with (or perpendicular to) the bottom portion of the trench in such structures, a gap may be formed in a lower portion of the trench after the fill-in of the upper portion of the trench. This can result in possible failure of the fill-in during this process of the filling-in of the trench. Thus, in order to facilitate trench filling-in, a sloped trench can be formed that includes sidewalls that are sloped with respect to a plane of the bottom portion of the trench.

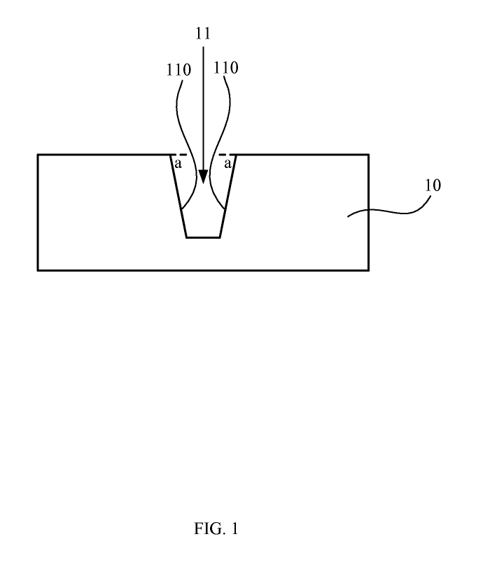

Referring now to FIG. 1, shown is a cross-sectional diagram of an example trench formation. In this example, trench 11 can be formed in semiconductor substrate 10. Sidewall 110 of trench 11 can be sloped, whereby angle “a” between sidewall 110 of trench 11 and a surface (e.g., top surface) of semiconductor substrate 10 may be greater than 0° and less than 90°. Because trench 11 is configured as a sloped trench with a wider opening and narrower bottom, a higher quality and convenient fill-in of polysilicon in trench 11 can be used form a gate of a power device or transistor. Alternatively, insulating material can be filled in trench 11 to form a shallow trench isolation (STI) structure.

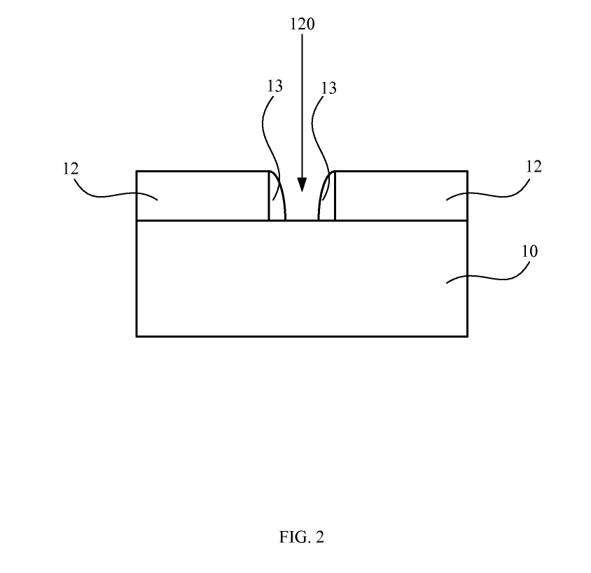

Referring now to FIG. 2, shown is a cross-sectional diagram of an example trench with spacer formation. In this example, a sloped trench can be formed by virtue of a spacer structure. For example, patterned mask layer 12 may be formed before trench formation. Spacer 13 can be formed in opening 120 of patterned mask layer 12. Because spacer 13 is thinner than mask layer 12 in this example, the blocking capacity of spacer 13 may be weaker than mask layer 12 during an etching process of semiconductor substrate 10, and in this way a sloped trench can be formed. Any suitable spacer structure or process (see, e.g., U.S. Pat. Nos. 5,945,352 and 6,033,968) can be utilized in particular embodiments. However, processing steps and material costs may be increased with this approach by use of a supplementary step of photomasking or film formation, which may also increase manufacturing costs of the integrated circuit.

In particular embodiments, a simplified process of trench formation that may lower costs and facilitate fill-in of polysilicon and/or an insulation material is provided. In one embodiment, a method of making a trench for a semiconductor device can include: (i) providing a semiconductor substrate; (ii) forming a patterned hard mask layer with an opening on the semiconductor substrate, where a thickness of the patterned hard mask layer is from about 100 nm to about 400 nm; and (iii) using the patterned hard mask layer as a mask, and etching the semiconductor substrate to form the trench in the semiconductor substrate.

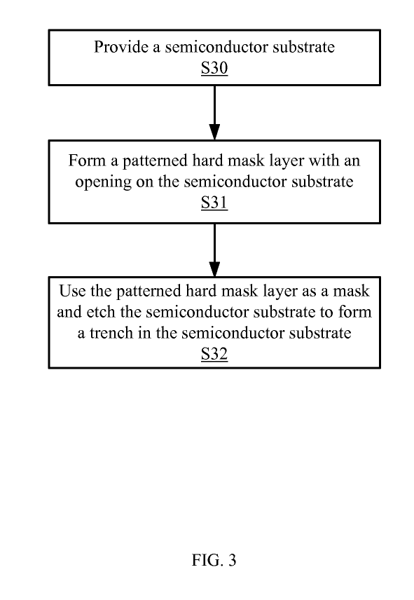

Referring now to FIG. 3, shown is a flow diagram of an example method of making a trench in accordance with embodiments of the present invention. At S30, a semiconductor substrate (e.g., a silicon substrate) can be provided. At S31, a patterned hard mask layer with an opening can be formed on the semiconductor substrate. For example, the thickness of the patterned hard mask layer can be from about 100 nm to about 400 nm. At S32, the patterned hard mask layer can be used as a mask, and the semiconductor substrate can be etched to form the trench in the semiconductor substrate.

In some applications, if a patterned hard mask layer with a thickness of from about 100 nm to about 400 nm is employed as a mask, a patterned hard mask layer portion that is adjacent to the opening may be more easily damaged and may fail to fully protect the semiconductor substrate under the opening. In this way, a trench with a wider opening and a narrower bottom can be formed. By use of such a structure in particular embodiments, a higher quality and more convenient fill-in of polysilicon in the trench can be accommodated to form a gate of a power device or transistor.

In particular embodiments, little or no additional manufacturing process or material cost may be needed for the trench formation, as compared to conventional approaches. A trench can be formed by a simplified and relatively low cost process that can facilitate fill-in with polysilicon to form a gate of a power device/transistor. Alternatively, an insulating material (e.g., an oxide) can be filled in the trench in order to achieve trench isolation, as opposed to transistor formation.

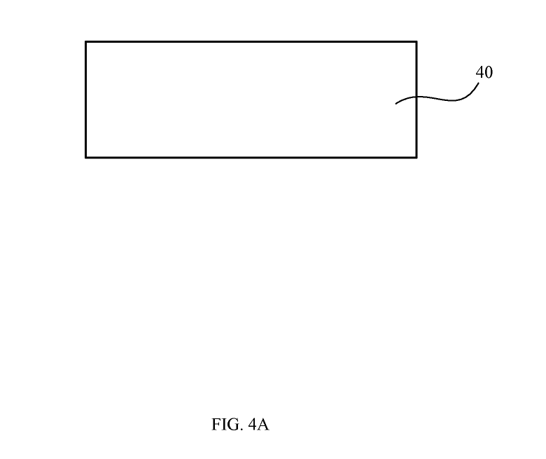

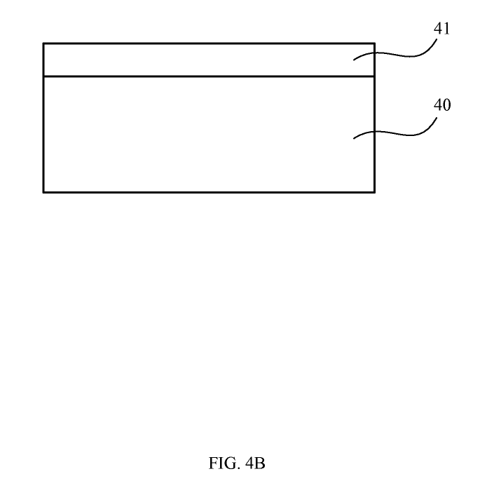

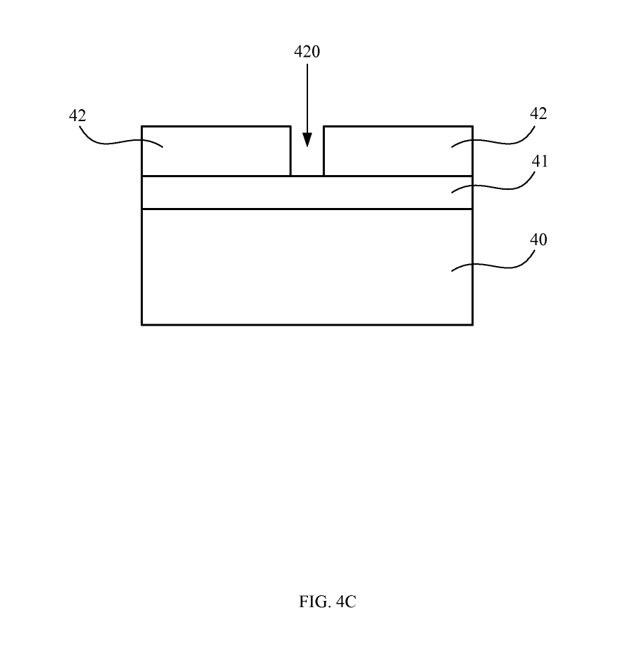

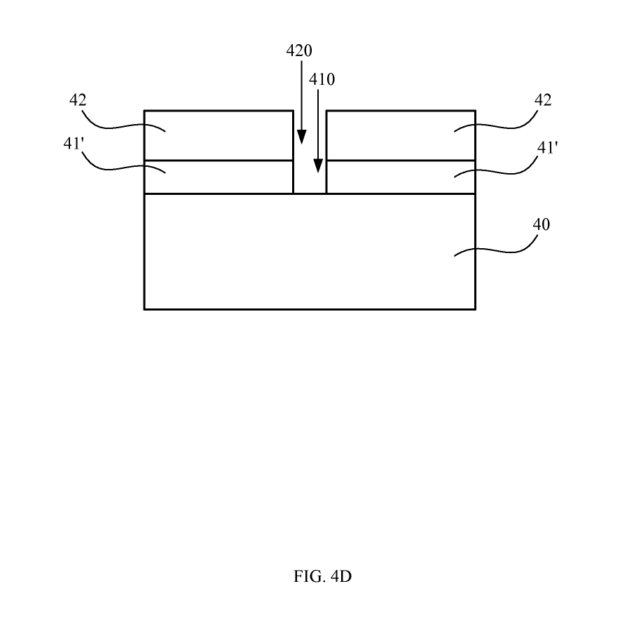

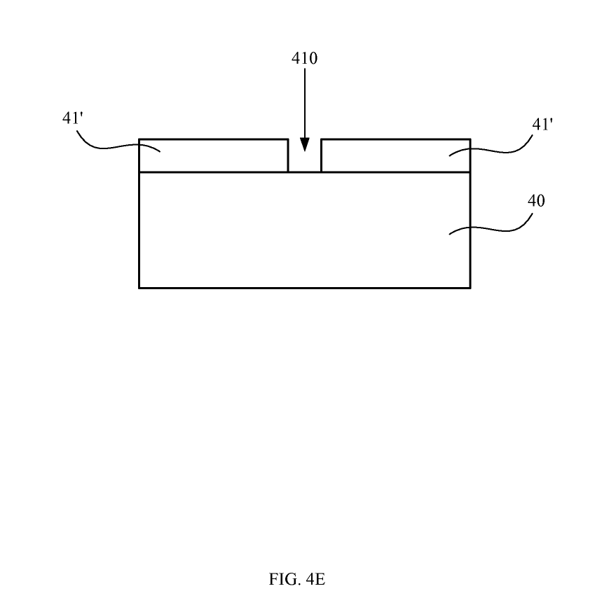

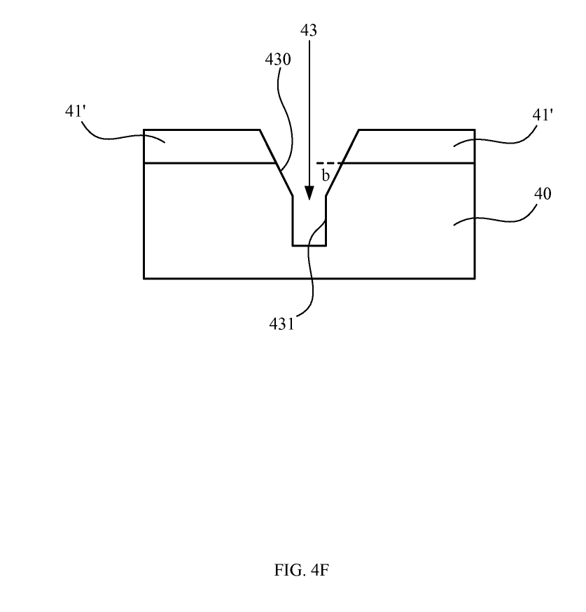

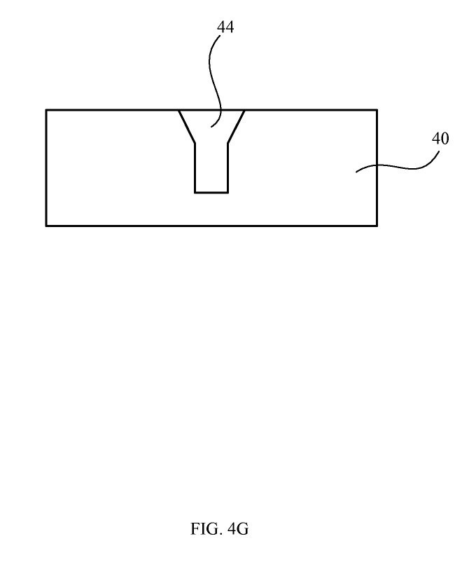

Referring now to FIGS. 4A-4G, shown are cross-sectional diagrams of example trench formation processing and structures, in accordance with embodiments of the present invention. In this particular example process, a trench may be employed to form a power transistor gate, or may be part of an isolation structure. As shown in FIG. 4A, semiconductor substrate 40 can be provided. For example, semiconductor substrate 40 can include a silicon substrate.

As shown in FIG. 4B, hard mask layer 41 can be formed on semiconductor substrate 40. For example, hard mask layer 41 can be an oxide or nitride material, such as silicon dioxide. Also for example, the thickness of hard mask layer 41 can be from about 100 nm to about 400 nm, such as 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 330 nm, 350 nm, 370 nm, or 400 nm.

As shown in FIG. 4C, patterned photoresist 42 can be formed on hard mask layer 41 with opening 420. The portion of hard mask layer 41 under opening 420 can thus be accordingly exposed. For example, a hard mask may be a material used as an etch mask in lieu of a polymer or other organic or “soft” resist material type of material. A pattern defined using a polymeric mask may be rapidly degraded during plasma etching because polymers tend to be etched relatively easily by oxygen, fluorine, chlorine or other reactive gases. Thus, a hard mask may stand up better to such reactive gases.

As shown in FIG. 4D, patterned photoresist 42 can be employed as a mask, and hard mask layer 41 may be etched to form patterned hard mask layer 41′ with opening 410. The portion of semiconductor substrate 40 under opening 410 can thus accordingly be exposed. The etching process can chemically remove layers (e.g., oxide) or portions of layers from the surface of a wafer during manufacturing. For many etch steps, part of the wafer can be protected from the etchant by a “masking” material (e.g., patterned photoresist, silicon nitride, etc.) that resists etching. Any suitable type of etching (e.g., wet etching, dry etching, plasma etching, etc.) can be employed to form the trenches in particular embodiments.

As shown in FIG. 4E, remaining patterned photoresist 42 may be de-coated or otherwise removed to expose patterned hard mask layer 41′ with opening 410. Any suitable process of removing photoresist 42, or other layers, can be employed in particular embodiments. For example, photo ashing can be utilized to remove photoresist 42. In some cases, a high temperature photo ashing or stripping can be performed, and in other cases a lower temperature “descum” photo ashing process can be employed.

Referring now to FIG. 4F, patterned hard mask layer 41′ can be employed as a mask, and semiconductor substrate 40 may be etched to form trench 43 therein. For example, when patterned hard mask layer 41′ with a thickness of from about 100 nm to about 400 nm is employed as such a mask, during the etching of semiconductor substrate 40, patterned hard mask layer 41′ portions adjacent to opening 410 may be more easily etched or damaged and may fail to fully protect the associated underneath portions of semiconductor substrate 40. Therefore, trench 43 with a wider opening at the top and a narrower bottom can be formed to accommodate convenient and efficient filling of polysilicon into trench 43.

Trench 43 in this particular example can include sidewall 430 adjacent to a top surface of semiconductor substrate 40, and sidewall 431 connected to sidewall 430. For example, sidewall 431 can be substantially perpendicular to (e.g., about 90° relative to) a surface (e.g., a top and/or bottom surface) of semiconductor substrate 40. Angle “b” between sidewall 430 and the surface of semiconductor substrate 40 may be acute (e.g., greater than about 15° but less than about 90°). Thus, trench 43 with a wider top opening and narrower bottom portion may achieve to accommodate convenient and efficient fill of polysilicon into trench 43.

In particular embodiments, when patterned hard mask layer 41′ with a thickness of from about 100 nm to about 110 nm is employed, angle “b” between sidewall 430 and the top surface of semiconductor substrate 40 may be from about 15° to about 18° . In another example, when patterned hard mask layer 41′ with a thickness of from about 150 nm to about 160 nm is employed, angle “b” between sidewall 430 and the surface of semiconductor substrate 40 may be from about 30° to about 33°.

In another example, when patterned hard mask layer 41′ with a thickness of from about 200 nm to about 210 nm is employed, angle “b” between sidewall 430 and the surface of semiconductor substrate 40 may be from about 45° to about 48°. In another example, when patterned hard mask layer 41′ with a thickness of from about 290 nm to about 300 nm is employed, angle “b” between sidewall 430 and the surface of semiconductor substrate 40 may be from about 72° to about 75°. In such ways, trench 43 in particular embodiments may have a wider opening and a narrower bottom portion, and can be configured to facilitate a fill of polysilicon into trench 43, e.g., for power transistor applications.

In particular embodiments, a polysilicon layer can also be included by a fill of polysilicon into trench 43 to form polysilicon layer 44 (see, e.g., FIG. 4G). Polysilicon can be filled more efficiently and conveniently to form a more reliable polysilicon layer 44 as compared to other approaches due to the profile of trench 43 with a wider opening and narrower bottom portion. In other examples, materials other than polysilicon (e.g., aluminum, oxide, etc.) can be filled-in to trench 43. For example, those skilled in the art will recognize that an isolation structure for layer can also be formed by filling an insulation material (e.g., an oxide) into trench 43 for applications when the trench structure is utilised to provide isolation (as opposed to being used for transistor formation). Thus, depending on the particular structure being formed, either conductive or insulating materials can be filled in trench 43.

In one embodiment, a semiconductor structure can include: (i) a semiconductor substrate; (ii) a trench in the semiconductor substrate, where the trench comprises a first sidewall adjacent to a surface of the semiconductor substrate, and second sidewall connected to the first sidewall, where an angle between the first sidewall and the surface is acute; and (iii) a fill layer in the trench, where the fill layer is selected from a polysilicon layer and an isolation layer.

As shown in FIGS. 4F and 4G, a semiconductor structure can include semiconductor substrate 40, trench 43 in semiconductor substrate 40, and polysilicon or isolation layer 44 in trench 43. For example, trench 43 can include sidewall 430 adjacent to the surface of semiconductor substrate 40, and sidewall 431 connected to sidewall 430. Angle “b” between sidewall 430 and the surface of semiconductor substrate 40 may also be acute (e.g., greater than about 15° but less than about 90°).

For example, angle “b” between sidewall 430 and the surface of semiconductor substrate 40 may be from about 15° to about 18°. In another example, angle “b” between sidewall 430 and the surface of semiconductor substrate 40 may be from about 30° to about 33°. In another example, angle “b” between sidewall 430 and the surface of semiconductor substrate 40 may be from about 45° to about 48°. In yet another example, angle “b” between sidewall 430 and the surface of semiconductor substrate 40 may be from about 72° to about 75°.

Particular embodiments can also include doping semiconductor areas surrounding trench 43 and/or doping materials filled-in to trench 43, in some cases. A dopant or doping agent can include a trace impurity element inserted into a semiconductor region in order to alter electrical properties thereof. Examples of dopants can include boron, arsenic, phosphorus, antimony, as well as other substances, depending on the dopant type, application, and/or semiconductor substrate. For example, the diffusion can include a heating or annealing process in order to activate the implanted dopants.

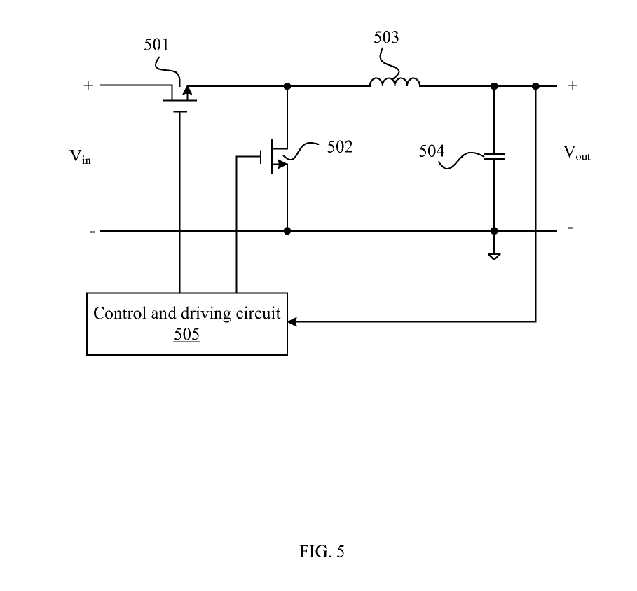

Referring now to FIG. 5, shown is a schematic diagram of an example switching voltage regulator that includes power devices as described herein. A switching voltage regulator is just one example of the circuitry that can be wholly or partially fabricated in the wafer structure and/or using processes of particular embodiments. In this example, power transistors 501 and 502, inductor 503, and capacitor 504 can form a synchronous buck power stage circuit. In other cases, other types of power stage or converter circuits (e.g., flyback, SEPIC, boost, buck-boost, etc.) can be formed. Control and driving circuit 505 (e.g., including a pulse-width modulation [PWM] controller) can receive an output signal of the power stage circuit, to form a closed-loop feedback control loop to control the switching state of power transistors 501 and 502. In this way, the output signal of the power stage circuit can be controlled to be substantially constant.

Of course, other integration or grouping of circuitry into different chips, ICs, or wafers can be accommodated in particular embodiments. In one example, a multi-chip packaging structure in particular embodiments can include power transistors 501 and 502 being integrated into a power device chip, and control and driving circuit 505 being integrated into a control chip. Since the power device may process a high voltage and/or a high current, the power device chip with a large area can be able to withstand a relatively high voltage and a relatively high current. Also, the power device may have good thermal characteristics for power supply integration.

For the integrated circuit of the switching voltage regulator shown in FIG. 5, if the carrying capacity of power transistor 502 is greater than that of power transistor 501, power transistor 502 may be much larger than power transistor 501. Thus, power transistor 502 (e.g., the synchronous power device) can be integrated in a single synchronous power device chip, and power transistor 501 (e.g., the main power device) as well as control and driving circuit 305 can be integrated in another single mixed chip. Further, power transistors 501 and/or 502 can be any suitable types of transistors or devices (e.g., super-junction MOS transistors, VDMOS, LDMOS, IGBT, etc.). For example, power transistors 501 and/or 502 can be formed via the trench structure and/or process as described herein.

The embodiments were chosen and described in order to best explain the principles of the invention and its practical applications, to thereby enable others skilled in the art to best utilize the invention and various embodiments with modifications as are suited to the particular use contemplated. It is intended that the scope of the invention be defined by the claims appended hereto and their equivalents.

What is claimed is:

1. A method of making a trench for a semiconductor device, the method comprising:
a) providing a semiconductor substrate;
b) forming a patterned hard mask layer with an opening on said semiconductor substrate, wherein a thickness of said patterned hard mask layer is from about 100 nm to about 400 nm; and
c) using the patterned hard mask layer as a mask, and etching said semiconductor substrate to form said trench in said semiconductor substrate.

2. The method of claim 1, wherein said patterned hard mask layer comprises silicon dioxide.

3. The method of claim 1, wherein said forming said patterned hard mask layer comprises:
a) forming a hard mask layer on said semiconductor substrate;
b) forming a patterned photoresist layer with an opening on said hard mask layer; and
c) using said patterned photoresist layer as a mask, and etching said hard mask layer to form said patterned hard mask layer with said opening.

4. The method of claim 1, wherein said trench comprises:
a) a first sidewall adjacent to a surface of said semiconductor substrate, wherein an angle between said first sidewall and said surface is acute; and
b) a second sidewall connected to said first sidewall.

5. The method of claim 4, wherein an angle between said second sidewall and said surface is about 90°.

6. The method of claim 4, wherein:
a) said thickness of said patterned hard mask layer is from about 100 nm to about 110 nm; and
b) said angle between said first sidewall and said surface is from about 15° to about 18°.

7. The method of claim 4, wherein:
a) said thickness of said patterned hard mask layer is from about 150 nm to about 160 nm; and
b) said angle between said first sidewall and said surface is from about 30° to about 33°.

8. The method of claim 4, wherein:
a) said thickness of said patterned hard mask layer is from about 200 nm to about 210 nm; and
b) said angle between said first sidewall and said surface is from about 45° to about 48°.

9. The method of claim 4, wherein:
a) said thickness of said patterned hard mask layer is from about 290 nm to about 300 nm; and
b) said angle between said first sidewall and said surface is from about 72° to about 75°.

10. A semiconductor structure, comprising:
a) a semiconductor substrate;
b) a trench in said semiconductor substrate, wherein said trench comprises a first sidewall adjacent to a surface of said semiconductor substrate, and second sidewall connected to said first sidewall, wherein an angle between said first sidewall and said surface is acute; and
c) a fill layer in said trench, wherein said fill layer is selected from a polysilicon layer and an isolation layer.

11. The semiconductor structure of claim 10, wherein an angle between said second sidewall and said surface is about 90°.

12. The semiconductor structure of claim 10, wherein said angle between said first sidewall and said surface is from about 15° to about 18°.

13. The semiconductor structure of claim 10, wherein said angle between said first sidewall and said surface is from about 30° to about 33°.

14. The semiconductor structure of claim 10, wherein said angle between said first sidewall and said surface is from about 45° to about 48°.

15. The semiconductor structure of claim 10, wherein said angle between said first sidewall and said surface is from about 72° to about 75°.
